(19) United States
(12) Patent Application Publication
(10) Pub. No.: US 2025/0054896 A1
(43) Pub. Date: Feb. 13, 2025

(54) SEMICONDUCTOR PACKAGE

(71) Applicant: Samsung Electronics Co., Ltd., Suwon-si (KR)

(72) Inventor: Jooyoung OH, Suwon-si (KR)

(21) Appl. No.: 18/779,409

(22) Filed: Jul. 22, 2024

(30) Foreign Application Priority Data
Aug. 8, 2023 (KR) 10-2023-0103446

(51) Int. Cl. H01L 23/00; H01L 23/31; H01L 23/498

(52) U.S. Cl. CPC H01L 24/29; H01L 23/49822; H01L 24/32; H01L 24/48; H01L 24/73; H01L 23/3107; H01L 23/49816; H01L 2224/26175; H01L 2224/29082; H01L 2224/32225; H01L 2224/48228; H01L 2224/73265

(57) ABSTRACT

A semiconductor package includes a package substrate including upper pads disposed at an upper portion of the package substrate, a solder resist layer disposed on the package substrate, the solder resist layer having a plurality of openings exposing the upper pads, a first adhesive layer disposed in at least a portion of an opening of the plurality of openings, a semiconductor chip disposed on the first adhesive layer, a second adhesive layer disposed between the first adhesive layer and the semiconductor chip, and a conductive member electrically connecting at least one of the upper pads and the semiconductor chip to each other.

### CROSS-REFERENCE TO RELATED APPLICATION(S)

This application claims benefit of priority to Korean Patent Application No. 10-2023-0103446 filed on Aug. 8, 2023, in the Korean Intellectual Property Office, the disclosure of which is incorporated herein by reference in its entirety.

### BACKGROUND

The present inventive concept relates to a semiconductor package.

With a reduction in weight and implementation of high performance of electronic devices, the development of semiconductor packages having a reduced size and high performance has been beneficial in the field of semiconductor packages. In order to reduce the size of semiconductor packages and implement high performance and high reliability in semiconductor packages, it is beneficial to increase contact reliability between a semiconductor chip and a package substrate on which the semiconductor chip is mounted.

### SUMMARY

An aspect of the present inventive concept provides a semiconductor package having improved reliability.

According to an aspect of the present inventive concept, there is provided a semiconductor package including a package substrate including upper pads disposed at an upper portion of the package substrate, a solder resist layer disposed on the package substrate, the solder resist layer having a plurality of openings exposing the upper pads, a first adhesive layer disposed in at least a portion of an opening of the plurality of openings, a semiconductor chip disposed on the first adhesive layer, a second adhesive layer disposed between the first adhesive layer and the semiconductor chip, and a conductive member electrically connecting at least one of the upper pads and the semiconductor chip to each other.

According to another aspect of the present inventive concept, there is provided a semiconductor package including a package substrate including upper pads and insulating layers disposed at an upper portion of the package substrate, a solder resist layer disposed on one surface of the package substrate, the solder resist layer having a first opening exposing an upper surface of at least one upper pad and a second opening exposing at least a portion of an upper surface of the insulating layer, the second opening having a width wider than that of the first opening, a first adhesive layer disposed in the second opening, the first adhesive layer covering the upper surface of the insulating layer exposed in the second opening, the first adhesive layer in contact with the solder resist layer, a second adhesive layer disposed on the first adhesive layer, and a semiconductor chip disposed on the second adhesive layer, the semiconductor chip electrically connected to a redistribution layer through the at least one upper pad exposed by the first opening.

According to another aspect of the present inventive concept, there is provided a semiconductor package including a package substrate including an interconnection layer, a first adhesive layer disposed on the package substrate, the first adhesive layer having a first coefficient of thermal expansion, a solder resist layer disposed at a level that is the same as that of the first adhesive layer, the solder resist layer having an opening exposing at least a portion of the interconnection layer of the package substrate, a semiconductor chip disposed on the first adhesive layer, and a second adhesive layer disposed between the first adhesive layer and the semiconductor chip, the second adhesive layer having a second coefficient of thermal expansion, lower than the first coefficient of thermal expansion.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor package according to an example embodiment of the present inventive concept;

FIG. 2 is a cross-sectional view taken along line I-I′ of FIG. 1.

FIG. 3 is a cross-sectional view of a semiconductor package according to an example embodiment of the present inventive concept;

FIG. 4 is a cross-sectional view of a semiconductor package according to an example embodiment of the present inventive concept;

FIG. 5 is a cross-sectional view of a semiconductor package according to an example embodiment of the present inventive concept;

FIG. 6 is a cross-sectional view of a semiconductor package according to an example embodiment of the present inventive concept; and

FIGS. 7 to 13 are cross-sectional views of a process of manufacturing a semiconductor package according to an example embodiment of the present inventive concept.

### DETAILED DESCRIPTION

Hereinafter, preferred example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which an element or component is actually arranged.

Items described in the singular herein may be provided in plural, as can be seen, for example, in the drawings. Thus, the description of a single item that is provided in plural should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

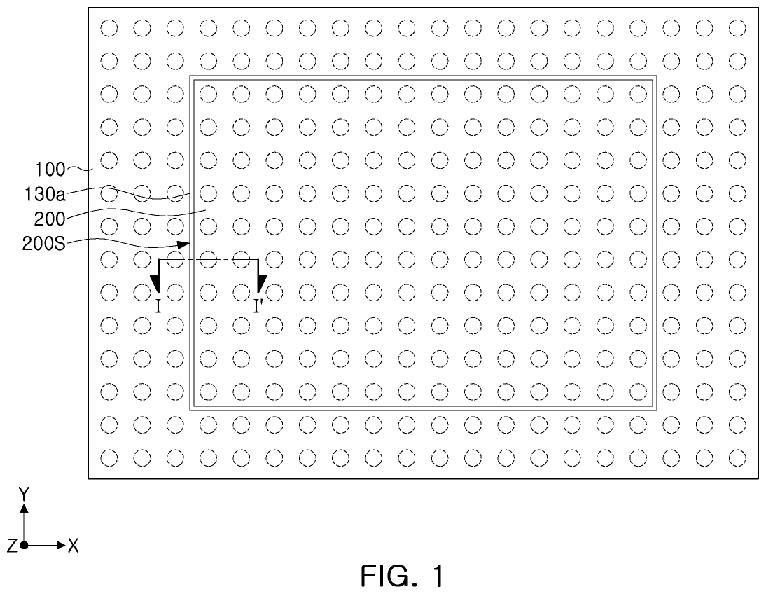

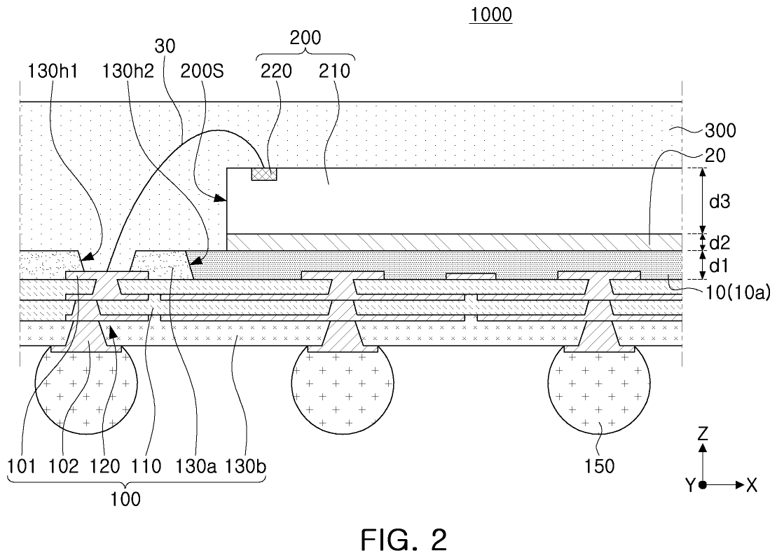

FIG. 1 is a plan view of a semiconductor package 1000 according to an example embodiment of the present inventive concept. FIG. 2 is a cross-sectional view taken along line I-I′ of FIG. 1.

Referring to FIGS. 1 and 2, the semiconductor package 1000 according to an example embodiment may include a package substrate 100, a semiconductor chip 200, and an encapsulant 300.

The package substrate 100 may be a support substrate on which the semiconductor chip 200 is mounted and may be a substrate for a semiconductor package. For example, the package substrate 100 may be a printed circuit board (PCB), a ceramic substrate, a glass substrate, a tape interconnection substrate, or the like. A body of the package substrate 100 may include a material different from another portion of the package substrate 100 depending on the type of substrate. For example, a package substrate 100 that is a printed circuit board may include a copper clad laminate body and/or an interconnection layer additionally laminated on a first surface or both the first surface and a second surface opposing the first surface of the copper clad laminate.

The package substrate 100 may include an insulating layer 110, upper pads 101, lower pads 102, and interconnection layers 120. Accordingly, the package substrate 100 may provide an electrical path for external transmission of signals from the semiconductor chip 200 disposed on an upper portion of the package substrate 100 and may also provide an electrical path for the transmission of external signals and power to the semiconductor chip 200.

The insulating layer 110 may include an insulating resin. The insulating resin may be and/or include a thermosetting resin such as an epoxy resin, a thermoplastic resin such as polyimide, or a resin, such as those listed previously, impregnated with an inorganic filler, including for example, “pre-impregnated” fibers and a partially cured polymer matrix (pre-preg), Ajinomoto build-up Film® (ABF), glass-reinforced epoxy laminate material (FR-4), or bismaleimide triazine (BT). For example, the insulating layer 110 may include a photosensitive resin such as a photo-imageable dielectric (PID). The insulating layer 110 may include a plurality of insulating layers stacked in a vertical direction. Depending on the process, the plurality of insulating layers may have indistinct boundaries therebetween.

The upper pads 101 may be disposed at an upper portion of the package substrate 100. An upper surface of the upper pads 101 may be exposed onto an upper surface of the package substrate 100. The upper pads 101 may be formed of and/or include, for example, at least one of aluminum (Al), copper (Cu), nickel (Ni), tungsten (W), platinum (Pt), and gold (Au). The lower pads 102 may be disposed a lower portion of the package substrate 100 and may be formed of and/or include a material that is the same as or similar to that of the upper pads 101. However, the materials of the upper pads 101 and the lower pads 102 are not limited to the above-described materials.

The interconnection layer 120 may electrically connect at least one of the upper pads 101, which are disposed on the upper portion of the package substrate 100, and at least one of the lower pads 102, which are disposed on the lower portion of the package substrate. The interconnection layer 120 may have a multilayer structure including an interconnection pattern and at least one via that may each be formed of and/or include, for example, aluminum (Al), gold (Au), cobalt (Co), copper (Cu), nickel (Ni), lead (Pb), tantalum (Ta), tellurium (Te), titanium (Ti), tungsten (W), or combinations thereof.

Passivation layers 130 may be disposed on upper and lower surfaces of the package substrate 100. The passivation layers 130 may include a first passivation layer such as a first solder resist layer 130a and a second passivation layer such as a second solder resist layer 130b. The passivation layers 130 may protect the upper pad 101, lower pad 102, and the like of the package substrate 100.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

The first solder resist layer 130a may be disposed on the upper surface of the package substrate 100. The first solder resist layer 130a may be in contact with at least a portion of an upper pad 101. The first solder resist layer 130a may have a first opening 130h1 exposing at least a portion of the upper surface of the upper pad 101. The first solder resist layer 130a may have a second opening 130h2 exposing at least a portion of the upper surface of the upper pad 101 and at least a portion of an uppermost insulating layer 110, among a plurality of insulating layers 110. The second opening 130h2 may have a width wider than a width of the first opening 130h1. A level of a lower surface of the second opening 130h2 may be lower than a level of a lower surface of the first opening 130h1. The first adhesive layer 10 may be disposed in the second opening 130h2.

The second solder resist layer 130b may be disposed on the lower surface of the package substrate 100. The second solder resist layer 130b may have an open portion exposing at least a portion of an interconnection pattern of the interconnection layer 120. A connection via may be disposed in the open portion and may electrically connect different levels of interconnection patterns in the interconnection layer 120. A lower pad 102 may be disposed below the connection via, and a plurality of connection bumps 150 may be disposed on a lower surface of the lower pad 102.

The material forming the passivation layers 130 may not be limited to any particular example. The material forming the passivation layers 130 may be, for example, a photosensitive insulating resin and a photosensitive insulating material, or may be solder resist (SR). When a solder resist is used as the material of the passivation layers 130, the passivation layer 130 may be referred to as a solder resist layer.

The plurality of connection bumps 150 may be disposed below the package substrate 100. Each of the connection bumps 150 may be disposed to be in contact with a corresponding lower pad 102 disposed on the lower surface of the package substrate 100. The connection bumps 150 may be formed of and/or include tin (Sn), indium (In), bismuth (Bi), antimony (Sb), copper (Cu), silver (Ag), zinc (Zn), lead (Pb), and/or alloys thereof.

The semiconductor chip 200 may include memory chips or memory devices storing or outputting data, based on an address command and control command received from the package substrate 100. For example, the semiconductor chip 200 may include logic chips (or “logic circuits”) such as a central processor (CPU), a graphics processing unit (GPU), a field programmable gate array (FPGA), an application processor (AP), a digital signal processor, a cryptographic processor, a microprocessor, a microcontroller, an analog-to-digital converter, and an application-specific IC (ASIC), and memory chips (or “memory circuits”) including a volatile memory such as dynamic RAM (DRAM) or static RAM (SRAM), and a non-volatile memory such as phase change RAM (PRAM), magnetic RAM (MRAM), resistive RAM (RRAM), or flash memory. A base material of the body 210 of the semiconductor chip 200 may be silicon (Si), germanium (Ge), gallium arsenide (GaAs), or the like. Various circuits may be formed in the body 210. A connection pad 220 may be used to electrically connect the semiconductor chip 200 to another component, and the connection pad 220 may be formed of and/or include a metal material such as aluminum (Al), copper (Cu), or the like, but the connection pad 220 is not particularly limited to these examples. The semiconductor chip 200 may be connected to the upper pad 101 of the package substrate 100 via a conductive member 30 electrically connecting, to each other, the connection pad 220 and the upper pad 101 having the upper surface exposed by the first opening 130h1.

In general, in a packaged device, a semiconductor chip may be disposed on one surface of a package substrate via an adhesive (for example, a die attach film (DAF)). During a board level reliability temperature cycle (BLR TC) test for the packaged device, a crack may occur at boundaries of the semiconductor chip and the crack may propagate to a solder ball disposed on the opposite surface of the package substrate. According to the present example embodiment, an additional adhesive may be disposed in an opening of a passivation layer, such as a solder resist layer, exposing a portion of the package substrate, thereby increasing a BLR TC lifespan.

The first adhesive layer 10 may be disposed in the second opening 130h2 of the first solder resist layer 130a. As illustrated in FIGS. 2, 4, and 6, the first adhesive layer 10 may be one of adhesive layers 10a, 10b, or 10c and may include different materials, according to an example embodiment. The first adhesive layer 10 may be in contact with at least a portion of an upper pad 101 and at least a portion of the insulating layer 110 exposed by the second opening 130h2. A side surface of the first adhesive layer 10 may be in contact with a side surface of the first solder resist layer 130a disposed between the first opening 130h1 and the second opening 130h2. Specifically, the first adhesive layer 10 may be in contact with a side surface of the second opening 130h2. An upper surface of the first adhesive layer 10 may be at a level that is the same as that of an upper surface of the first solder resist layer 130a. An edge region of the first adhesive layer 10 may be disposed to protrude beyond a side surface 200S of the semiconductor chip (e.g., have a greater lateral extent than the side surface in a plan view). The first adhesive layer 10 may be utilized to prevent a height of the semiconductor package 1000 from increasing and may additionally prevent a crack generated in an edge region of the semiconductor chip 200, which is disposed on the upper surface of the package substrate 100, from propagating to the interconnection layer 120 in the package substrate 100 and the connection bump 15 disposed on the lower surface of the package substrate 100.

A first thickness d₁ of the first adhesive layer 10 may be substantially the same as a thickness of the first solder resist layer 130a. The first thickness d₁, that is, a height from a lower surface of the first adhesive layer 10 in contact with an upper surface of the insulating layer 110 to an upper surface of the first adhesive layer 10, may be 30 um or less. For example, the first thickness d₁ may be the range of 10 um to 30 um, 15 um to 25 um, or 20 um to 25 um.

The first adhesive layer 10 may be formed of and/or include a material having a coefficient of thermal expansion less than that of the package substrate 100 and greater than those of the second adhesive layer 20 and the semiconductor chip 200. The first adhesive layer 10 may compensate for a difference in coefficient of thermal expansion between the package substrate 100, the second adhesive layer 20, and the semiconductor chip 200 to prevent or alleviate a warpage phenomenon of the semiconductor package 1000. The coefficient of thermal expansion of the package substrate 100 may have a value between the coefficient of thermal expansion of the interconnection layer 120 and the coefficient of thermal expansion of the insulating layer 110. For example, the coefficient of thermal expansion of the package substrate 100 may be about the same as the average value of the coefficients of thermal expansion of the interconnection layer 120 and the insulating layer 110, but the present inventive concept is not limited thereto.

Similarly, the first adhesive layer 10 may include a material having an elastic modulus greater than that of the package substrate 100 and less than those of the second adhesive layer 20 and the semiconductor chip 200. The first adhesive layer 10 may compensate for a difference in elastic modulus between the package substrate 100, the second adhesive layer 20, and the semiconductor chip 200 to prevent or alleviate a warpage phenomenon of the semiconductor package 1000.

In an example embodiment, the first adhesive layer 10 may be formed of and/or include an elastomer material as an adhesive material. The elastomer material May include at least one of styrene-based elastomer, olefin-based elastomer, polyester-based elastomer, urethane-based elastomer, polyamide-based elastomer, acrylic-based elastomer, or silicone-based elastomer. A coefficient of thermal expansion of the elastomer material may be less than that of the package substrate 100 and greater than those of the second adhesive layer 20 and the semiconductor chip 200. An elastic modulus of the elastomer material may be greater than that of the package substrate 100 and less than those of the second adhesive layer 20 and the semiconductor chip 200.

A second adhesive layer 20 may be disposed between the first adhesive layer 10 and the semiconductor chip 200. Any material capable of forming a bond between the semiconductor chip 200 and the first adhesive layer 10 may be used as the second adhesive layer 20. For example, the second adhesive layer 20 may include a DAF or an epoxy adhesive, but the present inventive concept is not limited thereto.

A second thickness d₂ of the second adhesive layer 20 may be equal to or less than the first thickness d₁ of the first adhesive layer 10. The second thickness d₂ may be, for example, about 50 um or less. For example, the second thickness may be in the range of 5 um to 50 um, 10 um to 30 um, or 15 um to 20 um. The first thickness d₁ may be greater than the second thickness d₂ by 5 um to 20 um. For example, the first thickness d₁ may be in the range of 5 um to 15 um or 10 um to 15 um.

The sum of the first thickness d₁ and the second thickness d₂ may be less than the third thickness d₃ of the semiconductor chip 200. For example, the sum of the first thickness d₁ and the second thickness d₂ may be about 1/10 or more of the third thickness d₃. For example, the sum of the first thickness d₁ and the second thickness d₂ may be in the range of 1/10 to ½, 1/10 to ¼, or ⅛ to ⅕ of the third thickness d₃.

The encapsulant 300 may seal the first solder resist layer 130a, the first and second adhesive layers 10 and 20, the conductive member 30, and the semiconductor chip 200 on the package substrate 100. The encapsulant 300 may be filled in the first opening 130h1. A lower surface of the encapsulant 300, disposed on the first solder resist layer 130a, may be at a vertical level that is the same as that of a lower surface of the encapsulant 300, disposed on the first adhesive layer 10. The encapsulant 300 may be formed of and/or include an insulating material such as an epoxy mold compound (EMC), but the material of the encapsulant 300 is not limited to this example.

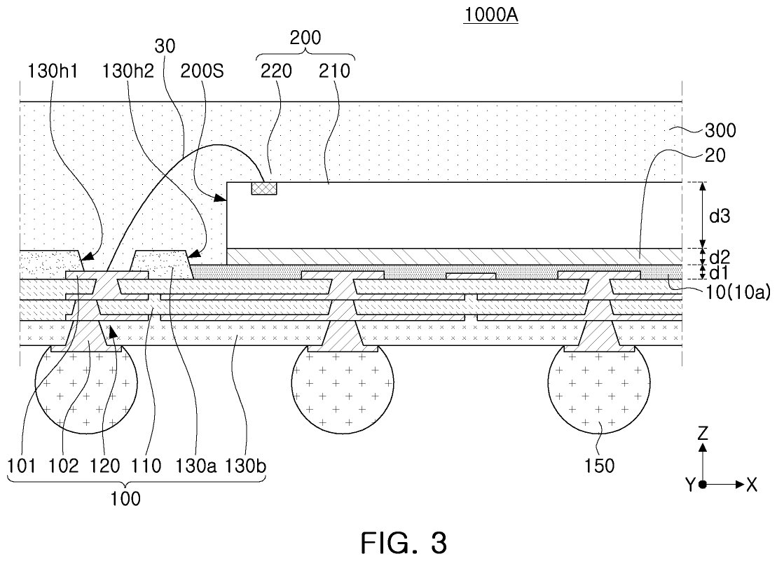

FIG. 3 is a cross-sectional view of a semiconductor package 1000A according to an example embodiment of the present inventive concept.

Referring to FIG. 3, the semiconductor package 1000A according to an example embodiment may have features that are the same as or similar to those described with reference to FIGS. 1 and 2 which may be indicated by duplicate reference characters and duplicate or repetitive descriptions may be omitted in the following description. The example embodiment of FIG. 3 differs from the example of FIG. 2 in that an upper surface level of a first adhesive layer 10 is lower than an upper surface level of a first solder resist layer 130a.

In an example embodiment, a first thickness d₁ of the first adhesive layer 10 may be less than a thickness of the first solder resist layer 130a. In an example embodiment, the first thickness d₁ may be about 25 um or less. For example, the first thickness d₁ may be in the range of 10 um to 25 um, or 15 um to 20 um.

In an example embodiment, at least a portion of an encapsulant 300 may be disposed in at least a portion of a second opening 130h2. In an example embodiment, a lower surface of the encapsulant 300, disposed on the first solder resist layer 130a, may be at a higher level than a lower surface of the encapsulant 300, disposed on the first adhesive layer 10.

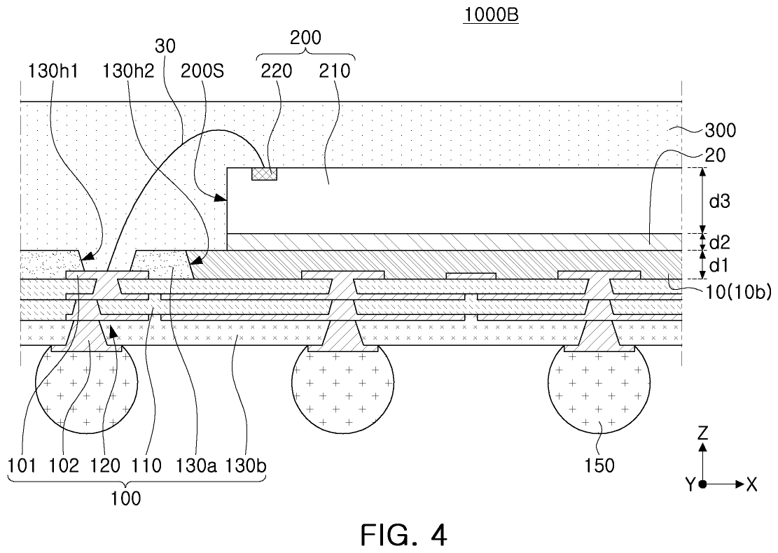

FIG. 4 is a cross-sectional view of a semiconductor package 1000B according to an example embodiment of the present inventive concept.

Referring to FIG. 4, the semiconductor package 1000B according to an example embodiment may have features that are the same as or similar to those described with reference to FIGS. 1 and 2 which may be indicated by duplicate reference characters and duplicate or repetitive descriptions may be omitted in the following description. The example embodiment of FIG. 4 differs from the example of FIG. 2 in that a first adhesive layer 10 and a second adhesive layer 20 are formed of and/or include the same material.

In an example embodiment, the first adhesive layer 10 and the second adhesive layer 20 may be formed of and/or include the same material, but a coefficient of thermal expansion of the first adhesive layer 10 may be greater than that of the second adhesive layer 20. For example, impurities may be added to a raw material of the first adhesive layer 10 or the raw material may be subject to heat treatment, such that an atomic arrangement in a crystal lattice of the material may be changed to affect the coefficient of thermal expansion.

In an example embodiment, the first adhesive layer 10 may be an adhesive layer 10b formed of and/or including a DAF or an epoxy adhesive, but the present inventive concept is not limited thereto.

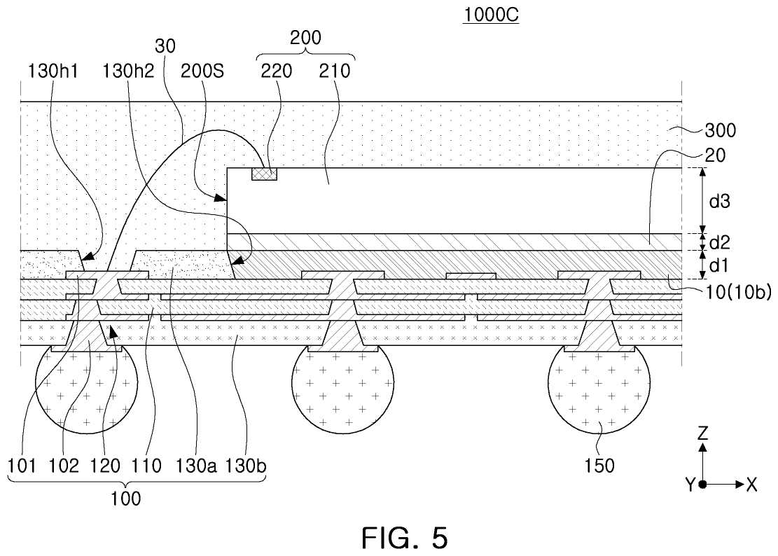

FIG. 5 is a cross-sectional view of a semiconductor package 1000C according to an example embodiment of the present inventive concept.

Referring to FIG. 5, the semiconductor package 1000C according to an example embodiment may have features that are the same as or similar to those described with reference to FIG. 4 which may be indicated by duplicate reference characters and duplicate or repetitive descriptions may be omitted in the following description. The example embodiment of FIG. 5 differs from the example of FIG. 4 in that a side surface of a first adhesive layer 10 does not extend beyond a side surface 200S of a semiconductor chip.

In an example embodiment, at least a portion of the side surface of the first adhesive layer 10 may be vertically aligned with a side surface of a second adhesive layer 20. An upper surface of the first adhesive layer 10 may be in complete contact with a lower surface of the second adhesive layer 20. In the present example embodiment, depending on the manufacturing process, a width of a first solder resist layer 130a, disposed between a first opening 130h1 and a second opening 130h2, may be formed to be wider than that of a corresponding first solder resist layer 130a illustrated in FIG. 4. In an example embodiment, an encapsulant 300 may not be in contact with an upper surface of the first adhesive layer 10.

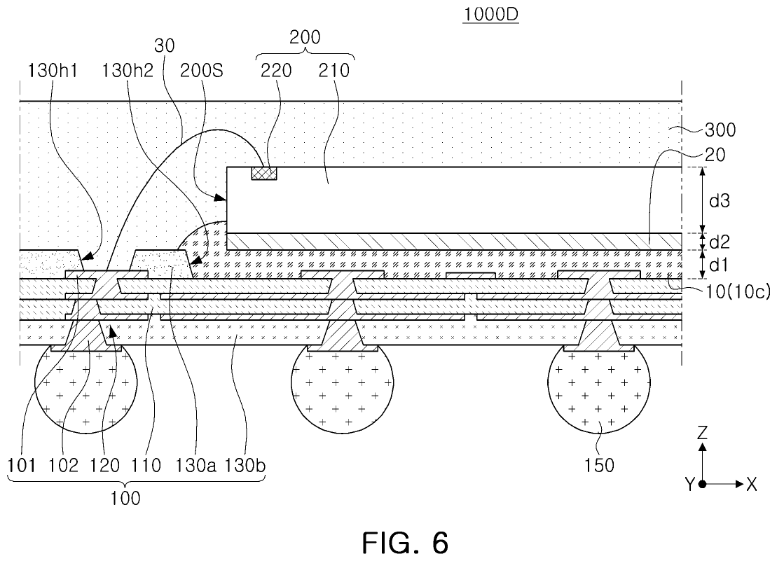

FIG. 6 is a cross-sectional view of a semiconductor package 1000D according to an example embodiment of the present inventive concept.

Referring to FIG. 6, the semiconductor package 1000D according to an example embodiment may have features that are the same as or similar to those described with reference to FIGS. 1 and 2 which may be indicated by duplicate reference characters and duplicate or repetitive descriptions may be omitted in the following description. The example embodiment of FIG. 6 differs from the example of FIG. 2 in that a first adhesive layer 10 is an underfill layer 10c including an underfill material.

In an example embodiment, an upper surface of a central region of the underfill layer 10c may be at a level that is the same as an upper surface of a first solder resist layer 130a. At least a portion of an edge region of the underfill layer 10c may be disposed to protrude from a second opening 130h2. A portion of the underfill layer 10c, protruding from the second opening 130h2, may be at a level that is higher than that of the upper surface of the first solder resist layer 130a. At least a portion of the underfill layer 10c, protruding from the second opening 130h2, may be in contact with at least a portion of the upper surface of the first solder resist layer 130a, a side surface of a second adhesive layer 20, and at least a portion of a lower side portion of a semiconductor chip 200.

The underfill layer 10c may be formed of and/or include a thermosetting resin such as an epoxy resin and/or silicone resin, but the present inventive concept is not limited thereto. For example, the underfill layer 10c may further include a filler such as silica.

A coefficient of thermal expansion of the underfill layer 10c may be less than that of a package substrate 100 and greater than those of the second adhesive layer 20 and the semiconductor chip 200. An elastic modulus of the underfill layer 10c may be greater than that of the package substrate 100 and less than those of the second adhesive layer 20 and the semiconductor chip 200.

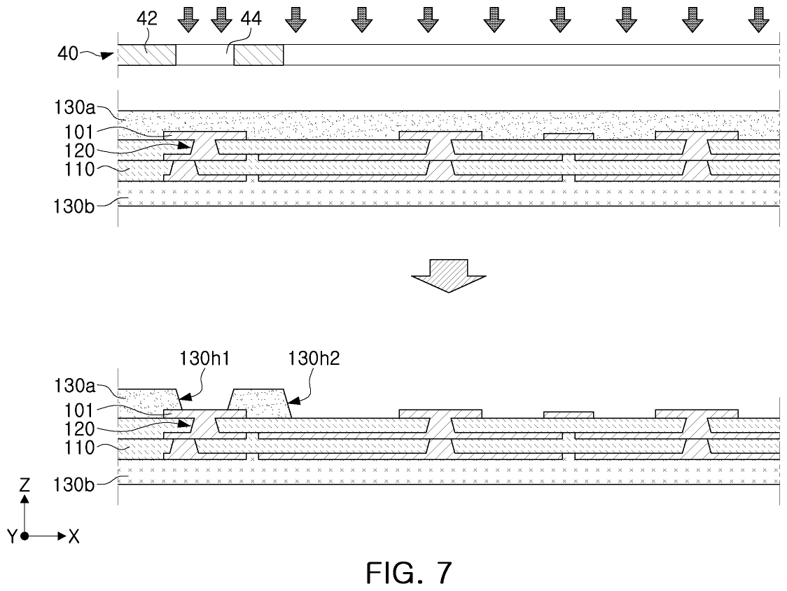

FIGS. 7 to 13 are cross-sectional views of a process of manufacturing a semiconductor package 1000 according to an example embodiment of the present inventive concept.

Referring to FIG. 7, a preliminary package substrate, including a plurality of insulating layers 110, a plurality of interconnection layers 120, and an upper pad 101, may be provided. A first solder resist layer 130a may be formed on a first surface of the preliminary package substrate by applying solder resist to surfaces of the insulating layers 110 and the upper pad 101. A second solder resist layer 130b may be formed on a second surface of the preliminary package substrate, opposite to the first surface, by applying solder resist to surfaces of the insulating layers 110 and the interconnection layers 120.

A mask 40 may be disposed on the first solder resist layer 130a. The mask 40 may include, for example, a first portion 42, painted with chrome (Cr), through which light does not pass in an exposure operation, and a second portion 44 through which light passes during the exposure operation. Accordingly, only a portion of the first solder resist layer 130a, disposed below the second portion 44 of the mask 40, may be selectively exposed and developed, thereby forming a first opening 130h1 and a second opening 130h2. At least a portion of an upper surface of the upper pad 101 may be exposed in the first opening 130h1. Upper and side surfaces of the upper pad 101 may be exposed and a surface of an uppermost insulating layer 110 may be exposed in the second opening 130h2. A portion of the first solder resist layer 130a, disposed below the first portion of the mask 40, may form a solder resist pattern.

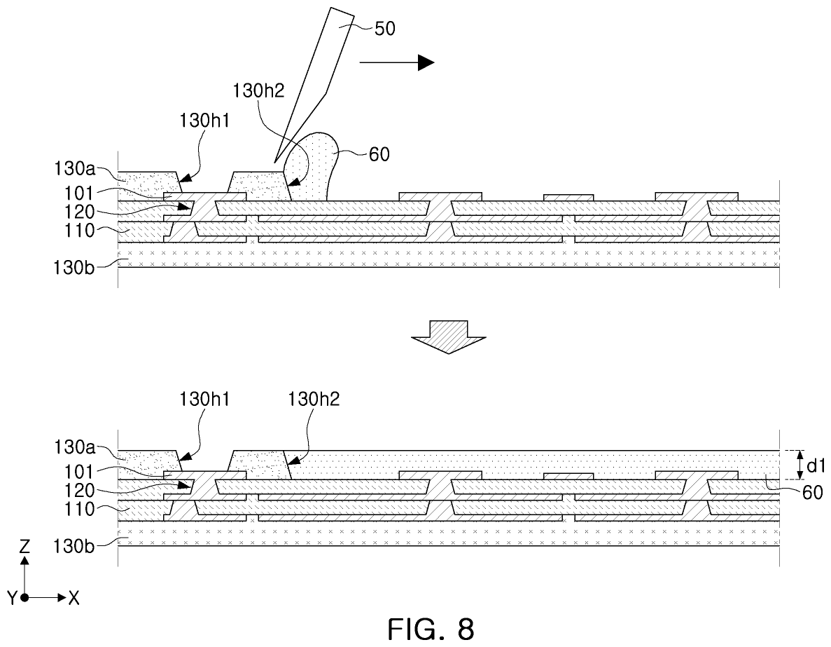

Referring to FIG. 8, screen-printing may be performed to fill the second opening 130h2 with an adhesive 60. For example, the adhesive 60 may be placed on a surface of the insulating layer 110 exposed by the second opening 130h2, and the adhesive 60 may be spread within the second opening 130h2 using a squeezing means 50 such as a squeegee. According to an example embodiment, various types of adhesives may be used as the adhesive 60. For example, referring to FIG. 2, the adhesive 60 may be an adhesive material formed of and/or including an elastomer material. Referring to FIG. 4, the adhesive 60 may be an adhesive material formed of and/or including a DAF or an epoxy resin.

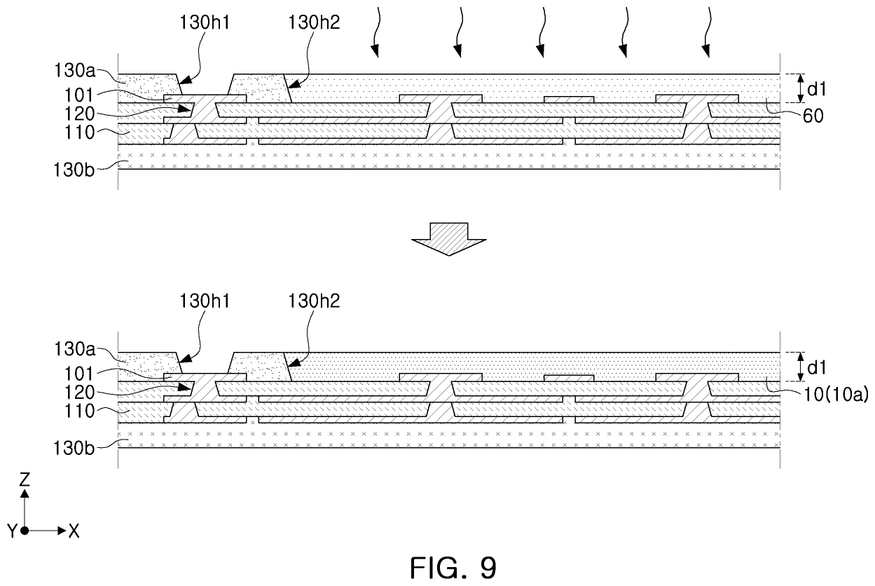

Referring to FIG. 9, a pre-curing operation may be performed to increase the viscosity of the adhesive by heating the adhesive 60 applied on the insulating layer 110. It may be preferable to perform the pre-curing operation immediately after the screen-printing operation. For example, it may be preferable to set a pre-curing time within a screen-printing cycle time in consideration of workability. A general screen-printing cycle time may be 45 seconds, such that the pre-curing time may be less than 45 seconds, preferably about 30 seconds.

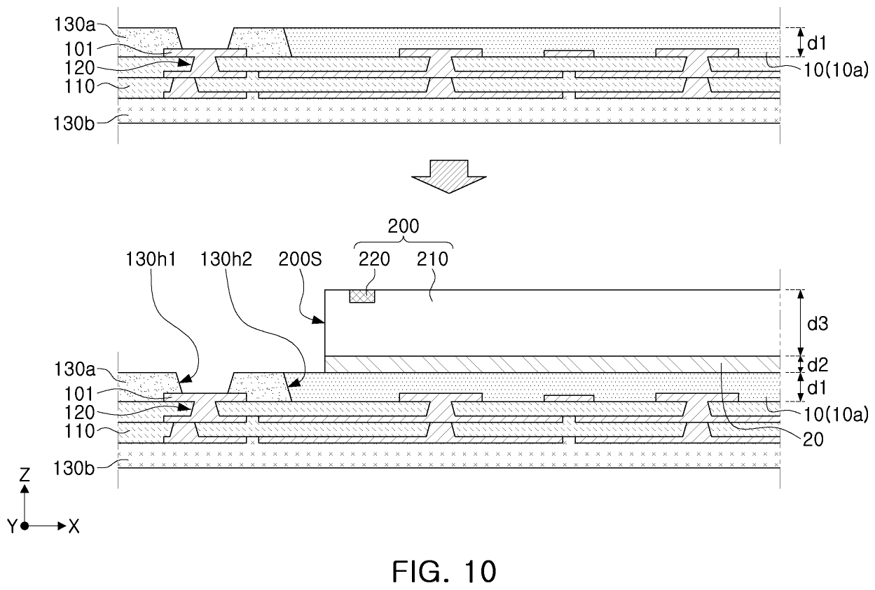

Referring to FIG. 10, a die attach operation may be performed to attach a semiconductor chip 200 to a first adhesive layer 10. The semiconductor chip 200 may be provided with a second adhesive layer 20 attached to one surface thereof. The semiconductor chip 200 may be attached to the first adhesive layer 10 such that a side surface 200S thereof is closer to a central region of a package substrate 100 than a side surface of the first adhesive layer 10.

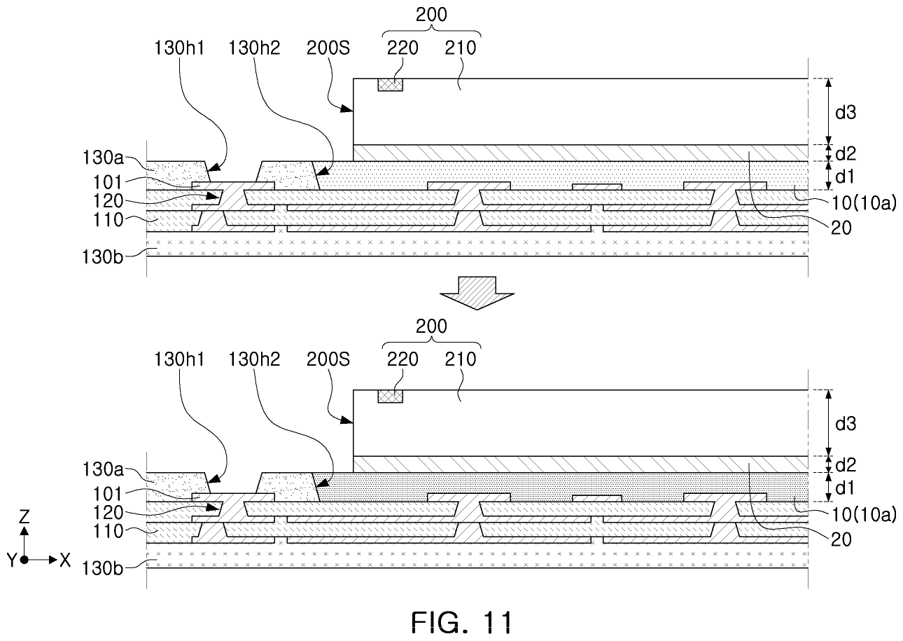

Referring to FIG. 11, a main curing operation may be performed to completely cure the first adhesive layer 10 by heating the first adhesive layer 10. The main curing operation may be performed by storing, in a curing oven, a first preliminary semiconductor package for which the die attach operation is completed.

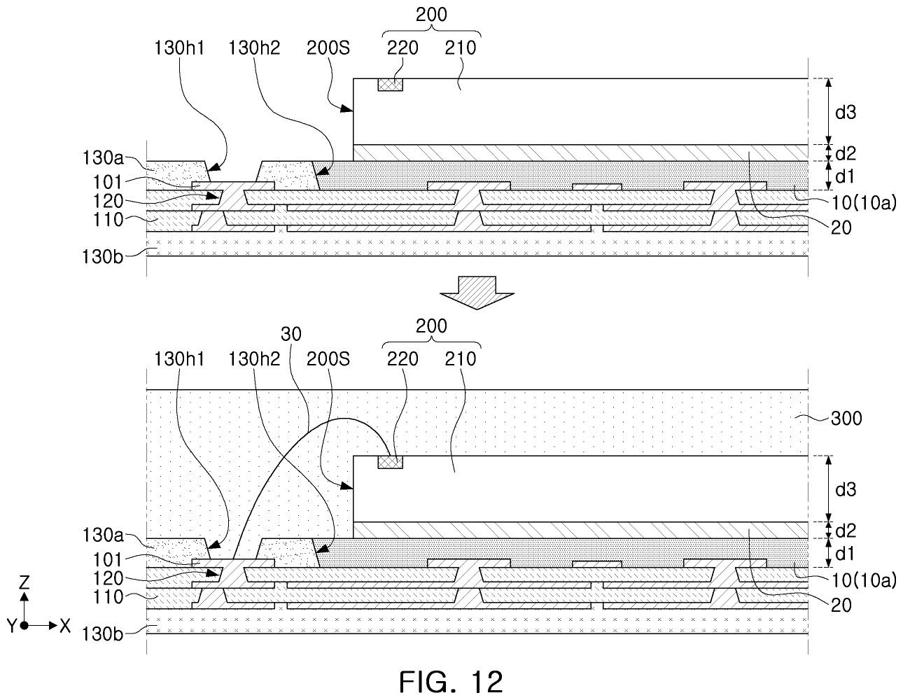

Referring to FIG. 12, a conductive member 30 may be formed to electrically connect a connection pad 220 of the semiconductor chip 200 to the upper pad 101 being exposed in the first opening 130h1. Subsequently, an encapsulant 300 may fill the first opening 130h1 on the preliminary package substrate, and may seal the first solder resist layer 130a, surfaces of the first and second adhesive layers 10 and 20, the conductive member 30, and the semiconductor chip 200 in a covering manner.

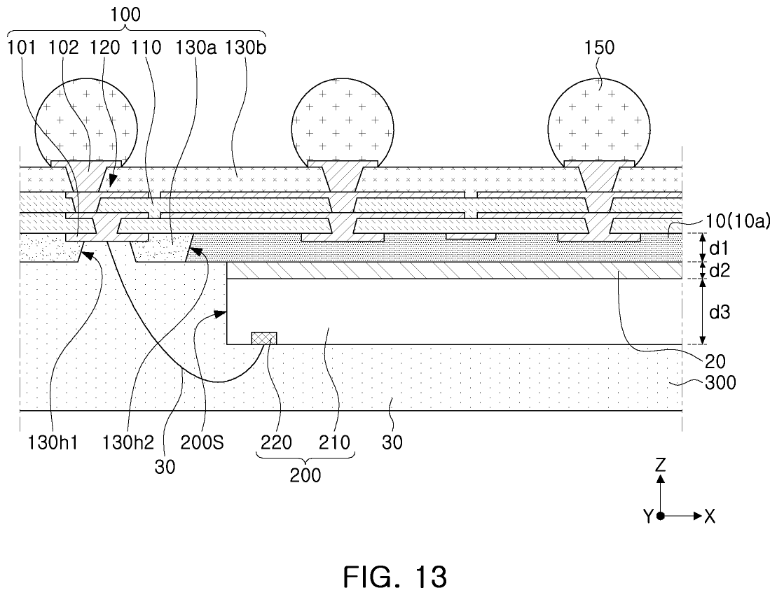

Referring to FIG. 13, a second preliminary semiconductor package filled with the encapsulant 300 may be provided to be face-up (e.g., inverted relative to the previous descriptions). As described with reference to FIG. 6, a mask may be disposed on the second solder resist layer 130b disposed on a lower surface of the package substrate 100, and a portion of the second solder resist layer 130b may be etched to form a plurality of openings. A connection via may be formed in the opening, and a lower pad 102 may be formed on a level higher than that of the second solder resist layer 130b. Subsequently, connection bumps 150 may be attached to the lower pad 102.

According to example embodiments of the present inventive concept, a thickness of an adhesive structure between a semiconductor chip and a package substrate may be increased, thereby providing a semiconductor package having improved reliability.

While example embodiments have been shown and described above, it will be apparent to those skilled in the art that modifications and variations could be made without departing from the scope of the present inventive concept as defined by the appended claims.

What is claimed is:

1. A semiconductor package comprising:
a package substrate including upper pads disposed at an upper portion of the package substrate;
a solder resist layer disposed on the package substrate, the solder resist layer having a plurality of openings exposing the upper pads;
a first adhesive layer disposed in at least a portion of an opening of the plurality of openings;
a semiconductor chip disposed on the first adhesive layer;
a second adhesive layer disposed between the first adhesive layer and the semiconductor chip; and
a conductive member electrically connecting at least one of the upper pads and the semiconductor chip to each other.

2. The semiconductor package of claim 1, wherein
a side surface of the first adhesive layer extends beyond a side surface of the semiconductor chip, and
the side surface of the first adhesive layer is in contact with a side surface of at least a portion of the openings of the solder resist layer.

3. The semiconductor package of claim 1, wherein an upper surface of the first adhesive layer is at a level that is the same as that of an upper surface of the solder resist layer.

4. The semiconductor package of claim 1, wherein an upper surface of the first adhesive layer is at a level that is lower than that of an upper surface of the solder resist layer.

5. The semiconductor package of claim 1, wherein the first adhesive layer is thicker than the second adhesive layer.

6. The semiconductor package of claim 5, wherein the first adhesive layer is thicker than the second adhesive layer by a thickness in the range of 5 um to 20 um.

7. The semiconductor package of claim 1, wherein the sum of thicknesses of the first and second adhesive layers is 0.25 times or less that a thickness of the semiconductor chip.

8. The semiconductor package of claim 1, wherein the first adhesive layer includes a first material having an elastic modulus less than that of a second material included in the second adhesive layer.

9. The semiconductor package of claim 8, wherein the first adhesive layer includes an elastomer material, and the second adhesive layer is a die adhesive film (DAF).

10. The semiconductor package of claim 1, wherein an edge region of the first adhesive layer is at a level that is higher than that of an upper surface of the solder resist layer.

11. The semiconductor package of claim 10, wherein at least a portion of the edge region of the first adhesive layer is in contact with at least a portion of the upper surface of the solder resist layer,
wherein at least a portion of the edge region of the first adhesive layer is in contact with at least a portion of a side surface of the semiconductor chip.

12. The semiconductor package of claim 11, wherein the first adhesive layer includes an underfill material.

13. A semiconductor package comprising:
a package substrate including upper pads and insulating layers disposed at an upper portion of the package substrate;
a solder resist layer disposed on a first surface of the package substrate, the solder resist layer having a first opening exposing an upper surface of at least one upper pad and a second opening exposing at least a portion of an upper surface of the insulating layer, the second opening having a width wider than that of the first opening;
a first adhesive layer disposed in the second opening, the first adhesive layer covering the upper surface of the insulating layer exposed in the second opening, the first adhesive layer in contact with the solder resist layer;
a second adhesive layer disposed on the first adhesive layer; and
a semiconductor chip disposed on the second adhesive layer, the semiconductor chip electrically connected to a redistribution layer through the at least one upper pad exposed by the first opening.

14. The semiconductor package of claim 13, wherein an upper surface of the first adhesive layer is at a level that is the same as that of an upper surface of the solder resist layer.

15. The semiconductor package of claim 14, wherein a coefficient of thermal expansion of the first adhesive layer is greater than that of the second adhesive layer.

16. The semiconductor package of claim 13, wherein an upper surface of the first adhesive layer is at a level that is lower than that of an upper surface of the solder resist layer.

17. A semiconductor package comprising:
a package substrate including an interconnection layer;
a first adhesive layer disposed on the package substrate, the first adhesive layer having a first coefficient of thermal expansion;
a solder resist layer disposed at a level that is the same as that of the first adhesive layer, the solder resist layer having an opening exposing at least a portion of the interconnection layer of the package substrate;
a semiconductor chip disposed on the first adhesive layer; and
a second adhesive layer disposed between the first adhesive layer and the semiconductor chip, the second adhesive layer having a second coefficient of thermal expansion, lower than the first coefficient of thermal expansion.

18. The semiconductor package of claim 17, wherein
the package substrate has a third coefficient of thermal expansion, and
the first coefficient of thermal expansion of the first adhesive layer is less than the third coefficient of thermal expansion.

19. The semiconductor package of claim 17, further comprising:
a conductive member electrically connecting, to each other, a connection pad of the semiconductor chip and the interconnection layer in the opening.

20. The semiconductor package of claim 19, further comprising:
an encapsulant filling the opening, the encapsulant surrounding the solder resist layer, the first and second adhesive layers, the conductive member, and the semiconductor chip,
wherein the encapsulant has a flat portion on the solder resist layer and the first adhesive layer.
